(19) United States
(12) Patent Application Publication
(10) Pub. No.: US 2023/0197919 A1
(43) Pub. Date: Jun. 22, 2023

(54) LIGHT IRRADIATION DEVICE AND LIGHT SOURCE UNIT

(71) Applicant: Ushio Denki Kabushiki Kaisha, Tokyo (JP)

(72) Inventors: Atsushi Takama, Tokyo (JP); Yoshihiro Kanahashi, Tokyo (JP)

(73) Assignee: Ushio Denki Kabushiki Kaisha, Chiyoda-ku, Tokyo, (JP)

(21) Appl. No.: 17/982,849

(22) Filed: Nov. 8, 2022

(30) Foreign Application Priority Data
Dec. 17, 2021 (JP) 2021-205048

(51) Int. Cl. H01L 33/64; H01L 27/15; H01L 23/467

(52) U.S. Cl. CPC H01L 33/648; H01L 23/467; H01L 27/156

(57) ABSTRACT

A light irradiation device includes a heat sink provided with a heat pipe, an LED substrate disposed to be in contact with the heat sink, and an enclosure that houses the heat sink and the LED substrate. The LED substrate has a light-emitting area in which a plurality of LED elements is arranged. When viewed from a direction orthogonal to a main surface of the LED substrate, part of the heat pipe is located inside the light-emitting area and another part of the heat pipe is located outside the light-emitting area.

### CROSS-REFERENCE TO RELATED APPLICATION(S)

This application claims priority from Japanese Priority Patent Application No. 2021-205048 filed on Dec. 17, 2021. The entire teachings of the above application are incorporated herein by reference.

### BACKGROUND ART

The present invention relates to light irradiation devices and light source units, particularly a light irradiation device and a light source unit using LED elements as a light source.

Printing apparatuses that perform printing using photo-curing ink that is cured by ultraviolet light irradiation (hereinafter referred to as “UV printing apparatuses”) are known. Conventionally, discharge lamps have been used as light sources for UV printing apparatuses. In recent years, however, LED (light-emitting diode) elements have begun to be used in place of discharge lamps because of their advantages such as low energy consumption and a long lifetime. However, since a single LED element has a low output, a plurality of LED elements is necessary to be arranged as a light source in order to radiate ultraviolet light at a light intensity that enables ink curing in a short period of time.

When a plurality of LED elements is made to be arranged as a light source, the problem of heat generation at the light source arises. Since the luminous efficiency and lifetime of LED elements decrease as their operating temperature increases, it is necessary to ensure high performance of exhausting heat from the viewpoint of improving efficiency and lifetime characteristics. For example, Japanese Patent 5940116 discloses technology related to cooling mechanisms provided in light source devices for UV printing apparatuses.

Currently, the market demands high-quality, high-speed printing technology. To meet these demands, it is necessary to further increase the light output from the light source. However, as mentioned above, when a light source is constituted by a plurality of LED elements, it is necessary to achieve even higher performance of exhausting heat because temperature rise is desirably avoided from the viewpoint of luminous efficiency and lifetime.

According to the configuration disclosed in Japanese Patent No. 5940116, the exhaust air after heat exchange through the heat sink is exhausted to the outside of the light irradiation device. From the viewpoint of further improving the light output as described above, it is desirable to increase the air volume of the cooling air supplied to the heat sink in order to improve the cooling efficiency.

In order to increase the air volume of the cooling air supplied to the heat sink, it is necessary to provide a large air inlet or air guide channel; however, such measures result in increasing the size of the entire light irradiation device. In particular, for light irradiation devices applied to UV printing apparatuses, such measures of increasing the size of the entire device are undesirable because the size of the entire device is determined, to a certain extent, by printing machines and printed matter, for example.

### SUMMARY OF THE INVENTION

In view of the above problem, it is desirable to provide a light irradiation device and a light source unit with improved cooling efficiency of LED elements without increasing the size of the entire device.

The light irradiation device of the present invention includes:
a heat sink provided with a heat pipe;
an LED substrate disposed to be in contact with the heat sink; and
an enclosure that houses the heat sink and the LED substrate,
the LED substrate has a light-emitting area in which a plurality of LED elements is arranged,
when viewed from a direction orthogonal to a main surface of the LED substrate, part of the heat pipe is located inside the light-emitting area and another part of the heat pipe is located outside the light-emitting area.

The term “light-emitting area” as used in the present specification refers to an area enclosed by the envelope connecting the outer periphery of the entire plurality of LED elements mounted on a single LED substrate.

A heat pipe is a component that contains a fibrous or mesh-like element called a wick and a liquid that evaporates by absorbing heat (hereinafter referred to as “working fluid”) inside a tube body made of metal. The heat pipe performs heat transport through the evaporation of working fluid due to absorbed heat, the condensation of the working fluid due to heat dissipation, and the high-speed movement of the evaporated and condensed working fluid inside the tube body.

The heat pipe absorbs the heat generated in the light-emitting area of the LED substrate, i.e., the heat generated by the lighting of the plurality of LED elements, and allows the heat to move sequentially to an area away from the light-emitting area.

Hence, the above configuration allows the heat generated in the light-emitting area to be sequentially exhausted faster, thereby improving the heat exhaust efficiency in the light-emitting area of the heat sink. In other words, the light irradiation device of the above configuration can further cool the LED elements mounted in the light irradiation device compared with that of the conventional configuration.

The light irradiation device described above may include:
a plurality of fins that are provided in the heat sink, and that form a separating portion for allowing cooling air to flow through the heat sink;
an air inlet through which the cooling air that has been drawn from the outside of the enclosure is introduced into the inside of the enclosure; and
an air inflow area in which the cooling air that has been drawn into the enclosure through the air inlet flows,
part of the heat pipe located outside the light-emitting area may be configured to be located closer to the air inflow area than the light-emitting area.

Furthermore, the above light irradiation device may be configured such that at least one end portion of the heat pipe is located outside the light-emitting area and closer to the air inflow area than the light-emitting area.

The cooling air that has been drawn from the outside of the enclosure flows through the vicinity of the heat pipe to which heat is transported from the light-emitting area, before reaching the surroundings of the light-emitting area. The cooling air that has absorbed heat to increase its temperature is pushed out by cooling air that is sequentially fed, thus it does not stay in the vicinity of the fins, and is exhausted out of the heat sink through the gap between the fins.

Hence, the above configuration allows the heat generated in the light-emitting area to be sequentially transported by the heat pipe to an area away from the light-emitting area. Then, the transported heat is sequentially exhausted by the cooling air having a relatively low temperature and flowing in from the outside of the enclosure. In other words, the light irradiation device of the present invention can exhaust the heat generated by the LED elements more efficiently, achieving higher cooling efficiency compared with the light irradiation device of the conventional configuration.

In the above light irradiation device, at least part of the heat pipe may be disposed along a first direction, and the separating portion may be formed in a manner that the cooling air flows along the first direction.

The above configuration allows the heat generated in the light-emitting area to be directly transported by at least part of the heat pipe toward the air inflow area in which cooling air without absorbing heat from the light-emitting area flows. In other words, the cooling air flows from the part to which the heat is transported toward the part in which the heat is absorbed. As a result, the cooling air can intensively absorb heat in the area to which heat is transported, thereby further improving the heat exhaust efficiency of the heat sink.

In the above light irradiation device, the enclosure may include a first air inlet and a first air guide channel through which the cooling air is introduced to one end edge portion of the fins, and a second air inlet and a second air guide channel through which the cooling air is introduced to the other end edge portion of the fins.

When the light-emitting area is formed on a center portion of the fin with respect to the first direction, and the end portions of the heat pipe to which the heat absorbed by the heat pipe is transported are disposed on the corresponding end edge portions, the above configuration allows the cooling air introduced from each of the first air guide channel and the second air guide channel to absorb the heat released from the heat pipe, and also to absorb the heat from the light-emitting area, resulting in exhausting the heat.

Furthermore, when heat is transported by one or more heat pipes from the center portion of the heat sink in the first direction to both end portions of the heat sink, the heat transported to both end portions thereof can be exhausted by the cooling air introduced from the respective air guide channels. Therefore, this configuration achieves the light irradiation device with higher heat exhaust efficiency.

In the light irradiation device described above, the heat sink may be configured such that a protruding length of the fins is shorter on the end edge portion than on the center portion.

In order to absorb more heat, the cooling air introduced between the fins of the heat sink preferably flows through close to the LED substrate, which is a heat source, and also the vicinity of a base body of the heat sink in which the heat pipe is provided, as much as possible. Hence, the area communicating between the air guide channel and the heat sink is designed to be in the vicinity of the base body of the heat sink as much as possible.

Increasing the total amount of cooling air supplied to the heat sink in order to improve cooling efficiency needs an increase in the cross-sectional area of the air guide channel as much as possible. However, simply enlarging the channel results in a larger size of the entire light irradiation device by the amount of the expanded air guide channel. Hence, for expanding the air guide channel, it is preferable to reduce some components in the light irradiation device to secure the area.

The above configuration allows the area communicating between the air guide channel and the heat sink to be narrowed such that the area is limited to the vicinity of the base body. The area where the protruding length of the fins is shortened can be used to expand the air guide channel. The heat sink may be configured such that the protruding length of the fins is relatively shortened in the area located outside the light-emitting area.

The light irradiation device described above may include an outlet channel through which the cooling air that has flowed through the separating portion is exhausted, a fan that is located in the outlet channel and that directs the cooling air from the air inlet to the outlet channel, and a wind shielding member provided between an inner wall face of the outlet channel and the fan.

If the fan is mounted in the vicinity of the heat sink, cooling air that has absorbed heat to become hot may flow backward in the outlet channel, posing a concern that the cooling air may mix with cooling air that has not absorbed heat flowing in from the air guide channel, and this mixed air may be introduced into the air inflow area. If this happens, the temperature of the cooling air introduced from the air guide channel rises, and the amount of cooling air flowing from the air guide channel into the heat sink is reduced, which may result in a decrease in cooling efficiency.

The above configuration prevents cooling air that has passed through the fan from flowing backward toward an upstream side through gaps in the surroundings of the fan.

In the above light irradiation device, part of the heat pipe may be arranged to overlap with the center of the light-emitting area when viewed from the direction in which the fin protrudes.

The “center of the light-emitting area” in the present specification corresponds to the center of gravity in the shape of the light-emitting area when viewed from a direction orthogonal to the main surface of the LED substrate.

The above configuration allows the heat pipe to absorb heat from the center of the light-emitting area, from which heat is difficult to be exhausted, and sequentially transport heat to the outside of the light-emitting area. This enables the heat pipe to exhaust a larger amount of heat from the LED substrate per unit time, further improving the cooling efficiency of the LED elements.

The above light irradiation device may be configured such that the LED substrate is in contact with at least part of the heat pipe.

Furthermore, in the above light irradiation device, the heat pipe may have a flattened shape at least in a portion at which the heat pipe is in contact with the LED substrate.

The above configuration improves the thermal conductivity between the LED substrate and the heat pipe, thereby improving the cooling efficiency of the LED elements.

The above light irradiation device may include a plurality of light source units including the LED substrate in which the light-emitting area is formed between both ends of two facing sides on the main surface, the heat pipe, and the heat sink, and the plurality of light source units may be arranged to emit light having a line shape.

In the present specification, “light-emitting area is formed between both ends” means that the LED elements are arranged such that the largest width of the light-emitting area is 80% or more with respect to the width of the LED substrate in a second direction.

The above configuration enables each light source unit in the light irradiation device to be replaced, for example, which makes maintenance, repair, or the like easier. In addition, the light irradiation device in the above configuration can be configured to adjust the number of light source units mounted therein and to select the light source unit that supplies electric power, thereby adjusting the length of light emitted therefrom in accordance with the size of the printed matter, for example.

The light source unit of the present invention may be a light source unit including the LED substrate, the heat sink, and the heat pipe; and the plurality of light source units may be arranged in the above light irradiation device in the second direction. The light-emitting areas may be formed between both ends of the LED substrates in the second direction on the first main surface of the LED substrate.

The present invention provides a light irradiation device and a light source unit with improved cooling efficiency of LED elements without increasing the size of the entire device.

### BRIEF DESCRIPTION OF DRAWINGS

FIG. 1 is a schematic upward perspective view of an embodiment of a light irradiation device.

FIG. 2 is an upward perspective view of the light irradiation device of FIG. 1, from which part of an enclosure has been removed.

FIG. 3 is an upward perspective view of the light irradiation device of FIG. 1, from which part of the enclosure has been removed.

FIG. 4 is a drawing of the light irradiation device of FIG. 2 when viewed from the +Y side.

FIG. 5A is an upward perspective view of a light source unit alone.

FIG. 5B is a drawing illustrating the light source unit shown in FIG. 5A, from which the LED substrate has been removed.

FIG. 5C is an upward perspective view of a light source unit alone.

FIG. 6A is a drawing of a light irradiation device when viewed from the -Z side.

FIG. 6B is a drawing illustrating the light irradiation device shown in FIG. 6A, from which part of the components has been removed.

FIG. 7 is a drawing of a light source unit from which the LED substrates have been removed, in an embodiment of a light irradiation device, when viewed from the -Z side.

FIG. 8 is a drawing of a light source unit from which the LED substrates have been removed, in an embodiment of a light irradiation device, when viewed from the -Z side.

FIG. 9 is a drawing of another embodiment of a light irradiation device from which part of the enclosure has been removed, when viewed from the +Y side.

FIG. 10 is a drawing of the light irradiation device of FIG. 9, when viewed from the -Z side.

### DETAILED DESCRIPTION OF THE EMBODIMENTS

### First Embodiment

Hereinafter, the light irradiation device of the present invention will be described with reference to the drawings. Not that each of the following drawings is illustrated schematically, and the dimensional ratios and numbers in the drawings do not necessarily correspond to the actual dimensional ratios and numbers.

### Light Irradiation Device 1

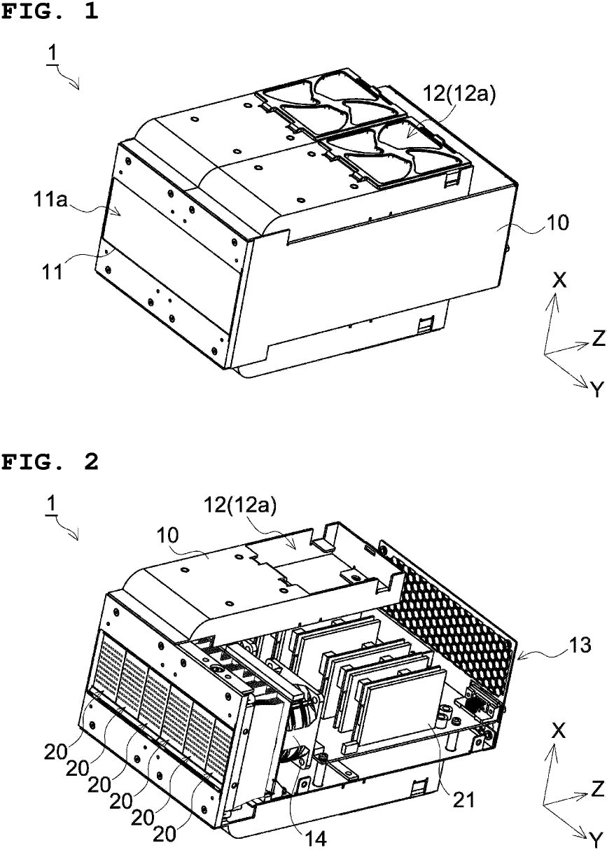

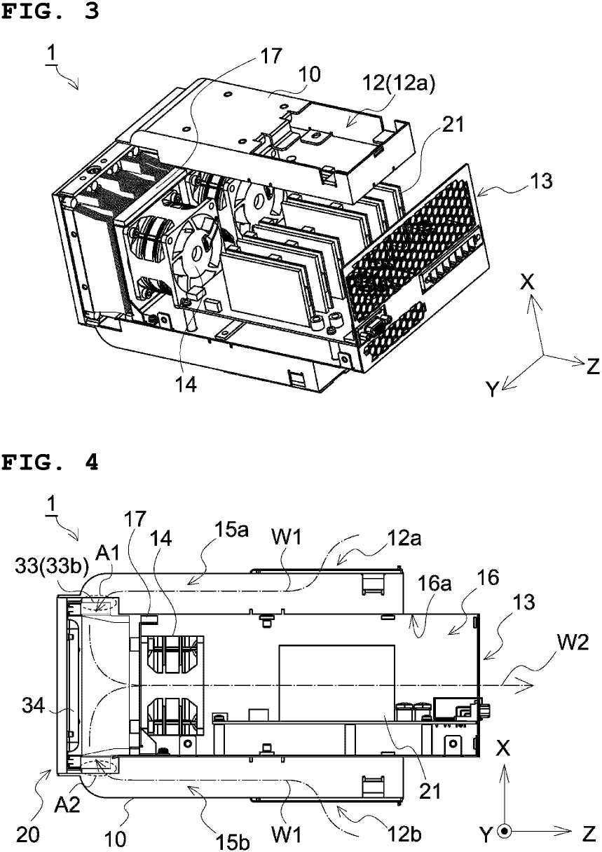

FIG. 1 is a schematic upward perspective view of a first embodiment of a light irradiation device 1. FIGS. 2 and 3 are drawings of the light irradiation device 1 of FIG. 1, from which part of an enclosure 10 has been removed, and each drawing is viewed from a different angle. As shown in FIG. 1, the light irradiation device 1 in the first embodiment includes an enclosure 10 that houses the light irradiation device 1, and the enclosure 10 is provided with a light-emission window 11, an air inlet 12, and an air outlet 13, as shown in FIGS. 1 to 3.

As shown in FIGS. 2 and 3, the light irradiation device 1 houses a plurality of light source units 20, a fan 14, and a power supply unit 21 inside the enclosure 10. Note that the first embodiment of the light irradiation device is provided with a first air inlet 12a in the side face of the +X side of the enclosure 10, and a second air inlet 12b in the side face of the -X side of the enclosure 10; however, the second air inlet 12b is not shown in FIGS. 1 to 3 because it is located on the -X side of the enclosure 10 and is hidden by other components.

Hereinafter, as shown in FIG. 1, the description is that a light emission surface 11a of the light-emission window 11 is considered to be located parallel to the XY plane, thus the direction orthogonal to the light emission surface 11a of the light-emission window 11, i.e., the optical axis of the principal ray of the emitted light, is described as the Z direction. As shown in FIG. 2, the direction in which the light source units 20 are arranged is described as the Y direction. Note that the X direction and the Y direction correspond to a “first direction” and a “second direction”, respectively.

When a direction is expressed with distinguishing a positive direction from a negative direction, the direction is described with a positive or negative sign, such as “+Z direction” or “-Z direction”; and when a direction is expressed without distinguishing a positive direction from a negative direction, the direction is simply described as “Z direction”.

FIG. 4 is a drawing of the light irradiation device 1 of FIG. 2 when viewed from the +Y side. As shown in FIG. 4, the enclosure 10 is provided with a first air guide channel 15a through which cooling air W1 that has been drawn from the first air inlet 12a is guided to a first air inflow area A1 that is located at an end edge portion of the +X side of a fin 33b of a heat sink 33, which will be described later, and a second air guide channel 15b through which the cooling air W1 that has been drawn from a second air inlet 12b is guided to a second air inflow area A2 that is located at an end edge portion of the -X side of the fin 33b. The fins shown in FIG. 4 exhibit a plane shape and are arranged in the Y direction; however, the fins 33b provided in the heat sink 33 may be configured to be dotted with fins each having a needle shape or a rod shape, for example. Even when a heat sink of this configuration is adopted, the light source unit 20 is designed such that cooling air flows between the fins in the X direction.

In the first embodiment, the air inlets (12a, 12b) are designed to draw air from the outside of the enclosure 10 into the inside of the enclosure 10 as the cooling air W1.

As shown in FIG. 1, the two first air inlets 12a of the first embodiment are provided in parallel in the Y direction; however, the number of the first air inlets 12a may be one, three, or more. The similar configuration can be adopted to that of the second air inlet 12b, which is hidden and not shown in FIG. 1.

Each of the air guide channels (15a, 15b) of the first embodiment, as shown in FIG. 4, is a channel intended to allow the cooling air W1 that has been drawn from the air inlets (12a, 12b) to pass through in the -Z direction and to be guided to each of the air inflow areas (A1, A2).

The outlet channel 16, as shown in FIG. 4, is a channel intended to allow cooling air W2 that has absorbed heat from the light source unit 20 to pass through in the +Z direction and to be guided to the air outlet 13.

In addition, the first embodiment is provided with the power supply unit 21 that supplies power to the light source unit 20 and the fan 14 in the outlet channel 16 (see FIG. 4), and is configured to exhaust the heat generated in the power supply unit 21 by the cooling air W2. The power supply unit 21 may be located outside the enclosure 10.

The fan 14 is disposed in the outlet channel 16 of the enclosure 10, as shown in FIG. 4. Starting an air blowing operation allows the fan 14 to draw the cooling air W1 from each air inlet (12a, 12b), to pass the cooling air W1 through the air guide channels (15a, 15b), between the fins 33b of the heat sink 33 (see below), and through the outlet channel 16 in that order, and to exhaust the cooling air W1 from the air outlet 13 as the heat-absorbed cooling air W2.

A wind shielding member 17 is provided between the fan 14 and an inner wall face 16a of the outlet channel 16, as shown in FIG. 4 in order to prevent the cooling air W2 from flowing backward from the surroundings of the fan 14 to the -Z side. The wind shielding member 17 is a component formed to fill the gap between the fan 14 and the inner wall face 16a of the outlet channel 16, and made of ethylene propylene diene rubber, for example. The shape of the wind shielding member 17 may be suitably adjusted in accordance with the shape of the gap between the fan 14 and the inner wall face 16a of the outlet channel 16.

Note that the wind shielding member 17 need not be provided in the case in which the fan 14 is mounted at a position closer to the air outlet 13 such that part of the cooling air W2 flowing backward is negligible. In addition, the air inlets (12a, 12b) and the fan 14 need not be provided in the case in which heat can be sufficiently exhausted by natural convection generated by temperature differences inside the enclosure, or in the case in which cooling mechanisms such as water-cooling is mounted.

The light-emission window 11 is a window provided to allow light emitted from the light source unit 20 to emit toward the -Z direction. The light-emission window 11 may be a simple aperture, but it may be covered with a material that transmits the light emitted from the light source unit 20 so as to prevent dust, for example, from adhering to the light source unit 20. When the opening is covered with such a material, examples of the material of the component constituting the light-emission window 11 include quartz glass and borosilicate glass.

### Light Source Unit 20

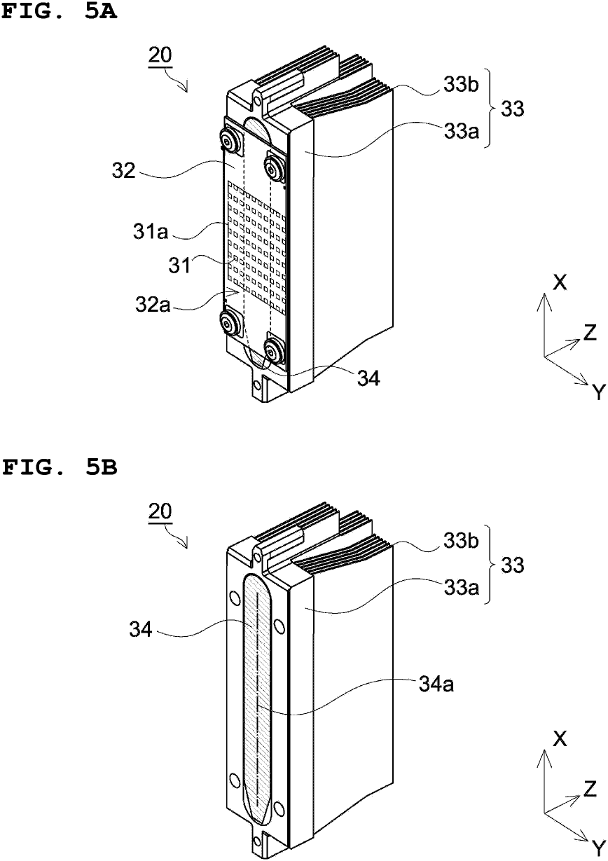

FIG. 5A is an upward perspective view of the light source unit 20 alone, and FIG. 5B is a drawing illustrating the light source unit 20 shown in FIG. 5A, from which the LED substrate 32 is removed. FIG. 5C is an upward perspective view of a light source unit 20 alone that is different from that in FIG. 5A. As shown in FIGS. 5A and 5B, the light source unit 20 includes a plurality of LED elements 31, an LED substrate 32, and a heat sink 33 including a base body 33a, a plurality of fins 33b, and a heat pipe 34. The specific configuration of the light source unit 20 will be described below in the section of the light source unit 20.

As shown in FIG. 5A, the LED substrate 32 is provided with the plurality of LED elements arranged in the X direction and the Y direction, forming a light-emitting area 31a. The light-emitting area 31a is defined, as shown in FIGS. 5A and 5C, as an area enclosed by the envelope of the outer periphery of the LED elements 31 that are arranged on a first main surface 32a of the LED substrate 32.

In the first embodiment, the LED substrate 32 has a size of (X, Y) = (70 mm, 25 mm), and is provided with the plurality of LED elements 31 arrayed in the X direction and the Y direction on the first main surface 32a thereof such that the light-emitting area 31a has a rectangular shape with a size of (X, Y) = (33 mm, 24 mm).

The LED element 31 in the first embodiment is an element that emits light having a main emission wavelength of 400 nm, which is a wavelength that exhibits the peak intensity in the intensity spectrum of the emitted light. However, any wavelength of the light emitted from the LED element 31 mounted can be selected.

In the case of light sources for curing ink used in UV printing apparatuses, the LED element 31 is preferably an element that emits light having a main emission wavelength within the range of 250 nm or more to 500 nm or less, and more preferably an element that emits light having a main emission wavelength within the range of 260 nm or more to 450 nm or less.

The LED elements 31 in the first embodiment are, as shown in FIG. 5A, are arranged on the first main surface 32a of the LED substrate 32 in the X direction and the Y direction in a manner of an equally spaced grid pattern. However, the LED elements 31 need not be arranged to be entirely equally spaced; as shown in FIG. 5C, it is possible to adopt a configuration in which the array of LED elements 31 is shifted parallel to a predetermined direction from the middle (in FIG. 5C, the rows aligned in the X direction are shifted parallel to the Y direction from the middle), for example.

As shown in FIG. 5A, the heat sink 33 includes the base body 33a, which is in contact with the LED substrate 32, and the plurality of plane-shaped fins 33b extending in the X direction and having the separating portions in the Y direction. The plurality of fins 33b, in order to widen the area constituting the air guide channel (15a, 15b) in the enclosure 10 as much as possible, is configured to such that a length of the protrusion in the side of the air inflow area (A1, A2) is shorter than that in the center portion in the X direction, in other words, the length of the protrusion in the Z direction is shorter in the side of the air inflow area (A1, A2) than that in the center portion.

In the heat sink 33 in the first embodiment, the base body 33a and the fins 33b are made of aluminum alloys; however, the base body 33a and the fins 33b can be made of other materials such as copper or magnesium alloys. If the heat sink 33 is configured to allow cooling air to flow in the vicinity thereof toward a predetermined direction using a fan or an air guide channel, the heat sink 33 need not be provided with the fins 33b.

The heat pipe 34 has a straight tube shape, as shown in FIG. 5B, and is embedded in the base body 33a of the heat sink 33 and is disposed such that the tube axis 34a is aligned along the X direction. The heat pipe 34 has a flat surface parallel to the XY plane formed in the -Z side thereof so as to be in contact over a wide area with the main surface that is the opposite side of the first surface 32a of the LED substrate 32.

The heat pipe 34 in the first embodiment uses a heat pipe of 70 mm in length in its extension direction, and the tube body of which is made of copper. The heat pipe 34 is known to have a higher cooling efficiency as the length in which the heat pipe 34 transports heat is longer. However, the heat pipe 34 having an excessively long length becomes difficult to secure an area for its placement. For this reason, the length of the heat pipe 34 mounted on the light irradiation device 1 in the extension direction is preferably from 50 mm or more to 100 mm or less, and more preferably from 70 mm or more to 80 mm or less.

The heat pipe 34, in order to be in contact with the LED substrate 32 on the surface, may be configured to have entirely a flattened shape, or may be configured to have a flattened shape only at the portion that is made to be in contact with the LED substrate 32. The heat pipe 34 may have a flat surface on the -Z side only at the portion that is made to be in contact with the LED substrate 32.

In addition, the heat pipe 34 may be configured to have a straight tube shape and to be entirely embedded in the base body 33a of the heat sink 33 so as not to be directly in contact with the LED substrate 32. Furthermore, the heat pipe 34 having a straight tube shape with its length in the extension direction being longer than the width of the heat sink 33 in the X direction may be employed.

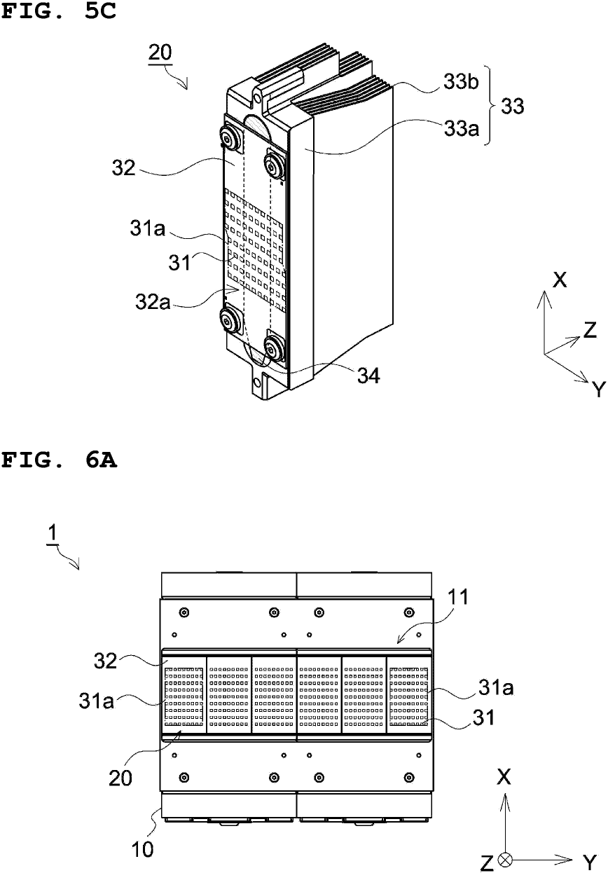

FIG. 6A is a drawing of the light irradiation device 1 when viewed from the -Z side, and FIG. 6B is a drawing of the light irradiation device 1 of FIG. 6A from which some components are removed. As shown in FIG. 6B, the heat pipe 34 is positioned, when viewed in the -Z direction, to overlap with the light-emitting area 31a, thus the center portion of the heat pipe 34 overlaps with the center 31c of the light-emitting area 31a. In other words, the heat pipe 34 is configured to absorb heat in the area overlapping with the light-emitting area 31a (the center portion in the first embodiment) when viewed in the Z direction, and to transport the absorbed heat to both end portions thereof.

The above configuration allows the heat generated in the light-emitting area 31a to be transported sequentially by the heat pipe 34 to a position closer to the air inflow area (A1, A2), which is away from the light-emitting area 31a. The heat that has been transported to a position closer to the air inflow area (A1, A2) is sequentially absorbed by the cooling air W1 and exhausted. The cooling air W1 flows in from each of the air guide channels (15a, 15b) and has a relatively low temperature because it has not yet absorbed heat in the enclosure 10. Therefore, the light irradiation device 1 can exhaust heat generated by the LED element 31 more efficiently than the conventional configuration of the light irradiation device, thereby achieving higher cooling efficiency.

In the light source unit 20 in the first embodiment, as shown in FIG. 6A, the LED elements 31 are arranged between both ends of the LED substrate 32 in the Y direction. Hence, the first embodiment of the light irradiation device 1 is configured to emit light through the light-emission window 11 in the form of a line extending in the Y direction from the plurality of light source units 20 arranged in the Y direction. The length of the light in the form of a line emitted from the light-emission window 11 can be adjusted by the number of the light source units 20 mounted in the light irradiation device 1.

In addition, as shown in FIG. 6A, the first embodiment of the light irradiation device 1 is configured to arrange the LED elements 31 between both ends of the enclosure 10 in the Y direction. Hence, this configuration, by connecting the plurality of light irradiation devices 1 each other, enables the length of the light emitted in the Y direction to be suitably adjusted in accordance with the size of the printed matter, etc.

The above description is that the light irradiation device 1 is capable of emitting light in the form of a line by arranging the plurality of light source units 20. However, it is also possible to configure a device that can emit light in the form of an even longer line by connecting the plurality of light irradiation devices 1 in the Y direction.

The light irradiation device 1 may be configured to be provided with only one light source unit 20 in which the light-emitting area 31a is formed for the desired size when, for example, the light irradiation device 1 is used only for objects to be irradiated that are small in size. Also as shown in FIG. 5A, the light-emitting area 31a need not be formed between both ends of the LED substrate 32 in the Y direction.

The enclosure 10 in the first embodiment is configured such that it can be disassembled into multiple components, as shown in FIGS. 2 and 3, but it can also be a box-shaped component in an integral configuration.

The fan 14 in the first embodiment is located in the outlet channel 16, but it can also be located in the air inlet 12 or the air guide channels (15a, 15b).

The heat sink 33 in the first embodiment is configured such that the base body 33a is directly in contact with the LED substrate 32; however, instead of the direct contact, the heat sink 33 may be disposed to be thermally in contact with the LED substrate 32 via the heat pipe 34.

### Second Embodiment

The following describes the configuration of the second embodiment of the light irradiation device 1 of the present embodiment, focusing on the points that differ from those of the first embodiment.

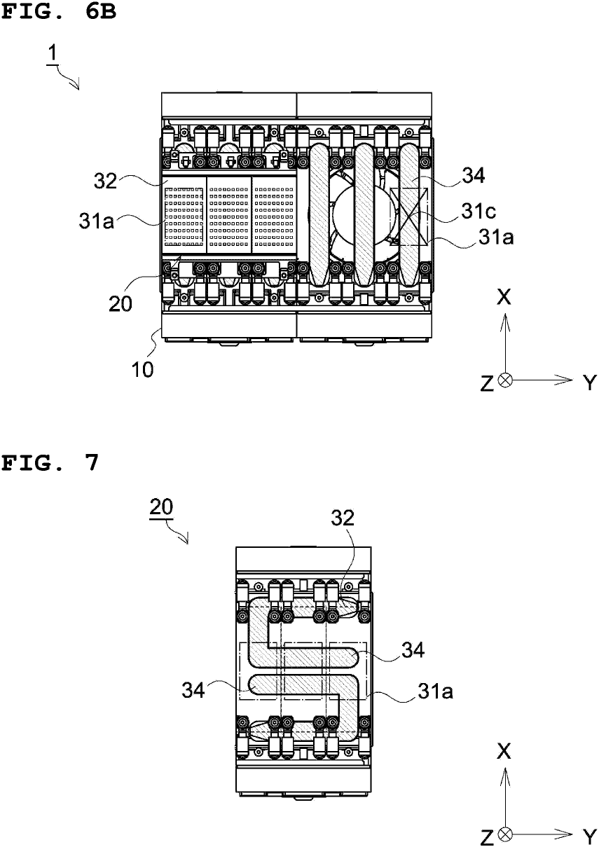

FIG. 7 is a drawing of the light source unit 20 in the second embodiment of the light irradiation device 1, from which the LED substrate 32 has been removed, when viewed from the -Z side. As shown in FIG. 7, in the light source unit 20 of the second embodiment, the heat pipe 34 has a U-shape and the plurality of them are arranged in the first direction. Although the LED element 31 is not shown in FIG. 7, for convenience of explanation, the light-emitting area 31a in the first embodiment is illustrated virtually with a single dotted line.

The heat pipe 34 has a higher cooling efficiency as the distance in which the heat is transported from its position in the light-emitting area 31a is longer. In other words, the heat pipe 34 itself has a higher cooling efficiency as the length in the extension direction per pipe is longer.

The heat pipe 34 provided in the light source unit 20 of the second embodiment is longer in the extension direction than the heat pipe 34 provided in the light source unit 20 of the first embodiment, thereby further improving the cooling performance.

The light source unit 20 in the second embodiment has a configuration in which the two U-shaped heat pipes 34 are arranged, but it is also possible to have a configuration in which one S-shaped heat pipe 34 is arranged to pass through the +Z side of each light-emitting area 31a.

### Third Embodiment

The configuration of the third embodiment of the light irradiation device 1 of the present embodiment will be described, focusing on the points that differ from those of the first embodiment and the second embodiment.

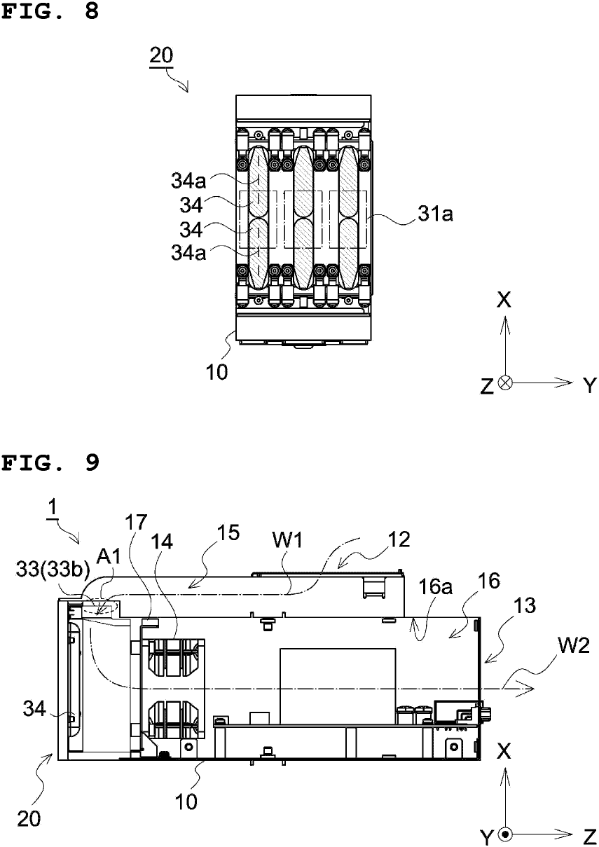

FIG. 8 is a drawing of the light source unit 20 of the third embodiment of the light irradiation device 1, from which the LED substrates 32 have been removed, when viewed from the -Z side. As shown in FIG. 8, the light source unit 20 in the third embodiment is provided with the plurality of heat pipes 34 each having a straight tube shape, in the X direction.

The light irradiation device 1 of the third embodiment has the heat pipes 34 shorter per pipe than those provided in the light source unit 20 of the first embodiment; however, the plurality of heat pipes 34 remove heat generated at a single light-emitting area 31a, thereby further improving the cooling performance.

### Another Embodiment

Hereinafter, another embodiment is described.

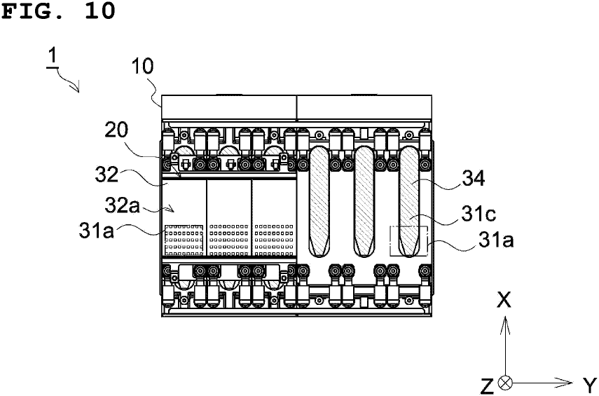

FIG. 9 is a drawing of another embodiment of the light irradiation device 1, from which part of the enclosure 10 is removed, when viewed from the +Y side with. FIG. 10 is a drawing of the light irradiation device 1 of FIG. 9, when viewed from the -Z side. FIG. 10 is illustrated with some components removed, as is similar to FIG. 6B, for convenience of explanation.

As shown in FIG. 9, another embodiment of the light irradiation device 1 differs from the first embodiment in that the air inlet 12 and air guide channel 15 are provided only on the +X side of the enclosure 10. In addition, as shown in FIG. 10, the light source unit 20 in another embodiment includes the light-emitting areas 31a formed not in the center portion on the first main surface 32a of the LED substrate 32 but at a position shifted to the -X side.

The light source unit 20 in another embodiment is also configured such that one end portion of the heat pipe 34 is located inside the light-emitting area 31a when viewed in the Z direction. In other words, the heat pipe 34 in this configuration absorbs heat at the one end portion located on the light-emitting area 31a and transports it to a position closer to the first air inflow area A1. Then, as shown in FIG. 9, the heat is absorbed by the cooling air W1 that is to be introduced into the first air inflow area A1 through the air guide channel 15.

The above configuration enables the light irradiation device 1 to be configured with only one air inlet 12 and one air guide channel 15, leading to downsizing the entire light irradiation device 1.

The above-mentioned configuration of the light irradiation device 1 is merely an example, and the present invention is not limited to each of the illustrated configurations.

What is claimed is:

1. A light irradiation device comprising:
a heat sink provided with a heat pipe;
an LED substrate disposed to be in contact with the heat sink; and
an enclosure that houses the heat sink and the LED substrate,
wherein the LED substrate has a light-emitting area in which a plurality of LED elements are arranged, and
when viewed from a direction orthogonal to a main surface of the LED substrate, part of the heat pipe is located inside the light-emitting area and another part of the heat pipe is located outside the light-emitting area.

2. The light irradiation device according to claim 1, further comprising:
a plurality of fins provided in the heat sink, that form a separating portion for allowing cooling air to flow through the heat sink;
an air inlet through which the cooling air that has been drawn from the outside of the enclosure is introduced into the inside of the enclosure; and
an air inflow area in which the cooling air that has been drawn into the enclosure through the air inlet flows,
wherein part of the heat pipe located outside the light-emitting area is configured to be located closer to the air inflow area than the light-emitting area.

3. The light irradiation device according to claim 2, wherein at least one end portion of the heat pipe is located outside the light-emitting area and closer to the air inflow area than the light-emitting area.

4. The light irradiation device according to claim 2, wherein at least part of the heat pipe is disposed along a first direction, and the separating portion may be formed in a manner that the cooling air flows along the first direction.

5. The light irradiation device according to claim 2, wherein the enclosure includes a first air inlet and a first air guide channel through which the cooling air is introduced to one end edge portion of the fins, and a second air inlet and a second air guide channel through which the cooling air is introduced to the other end edge portion of the fins.

6. The light irradiation device according to claim 2, wherein the heat sink is configured such that a protruding length of the fins is shorter on the end edge portion than on a center portion.

7. The light irradiation device according to claim 2, further comprising:
an outlet channel through which the cooling air that has flowed through the separating portion is exhausted;
a fan that is located in the outlet channel and that directs the cooling air from the air inlet to the outlet channel, and
a wind shielding member provided between an inner wall face of the outlet channel and the fan.

8. The light irradiation device according to claim 1, wherein part of the heat pipe is arranged to overlap with the center of the light-emitting area when viewed from the direction orthogonal to the main surface of the LED substrate.

9. The light irradiation device according to claim 1, wherein the LED substrate is in contact with at least part of the heat pipe.

10. The light irradiation device according to claim 9, wherein the heat pipe has a flattened shape at least in a portion at which the heat pipe is in contact with the LED substrate.

11. The light irradiation device according to claim 1, further comprising:
a plurality of light source units including the LED substrate in which the light-emitting area is formed between both ends of two facing sides on the main surface, the heat pipe, and the heat sink,
wherein the plurality of light source units is arranged to emit light having a line shape.

12. The light source unit mounted in the light irradiation device according to claim 11.
